(19) United States
(12) Patent Application Publication
(10) Pub. No.: US 2003/0193777 A1
(43) Pub. Date: Oct. 16, 2003

(54) Data center energy management system

(76) Inventors: Richard J. Friedrich, San Jose, CA (US); Chandrakant D. Patel, Fremont, CA (US)

Correspondence Address: HEWLETT-PACKARD COMPANY, Intellectual Property Administration, P.O. Box 272400, Fort Collins, CO, 80527-2400, US

(21) Appl. No.: 10/122,210

(22) Filed: Apr. 16, 2002

(51) Int. Cl. H05K 7/20; H05K 5/00; G06F 1/20; G05D 23/00; G05B 21/00; G05B 15/00; G05B 13/00; G01M 1/38; G06F 9/00

(52) U.S. Cl. 361/687; 709/100

(57) ABSTRACT

An energy management system for one or more computer data centers, including a plurality of racks containing electronic packages. The electronic packages may be one or a combination of components such as, processors, micro-controllers, high-speed video cards, memories, semi-conductor devices, computers and the like. The energy management system includes a system controller for distributing workload among the electronic packages. The system controller is also configured to manipulate cooling systems within the one or more data centers.

### FIELD OF THE INVENTION

This invention relates generally to data centers. More particularly, the invention pertains to energy management of data centers.

### BACKGROUND OF THE INVENTION

Computers typically include electronic packages that generate considerable amounts of heat. Typically, these electronic packages include one or more components such as CPUs (central processing units) as represented by MPUs (microprocessor units) and MCMs (multi-chip modules), and system boards having printed circuit boards (PCBs) in general. Excessive heat tends to adversely affect the performance and operating life of these packages. In recent years, the electronic packages have become more dense and, hence, generate more heat during operation. When a plurality of computers are stored in the same location, as in a data center, there is an even greater potential for the adverse effects of overheating.

A data center may be defined as a location, e.g., room, that houses numerous electronic packages, each package arranged in one of a plurality of racks. A standard rack may be defined as an Electronics Industry Association (EIA) enclosure, 78 in. (2 meters) wide, 24 in. (0.61 meter) wide and 30 in. (0.76 meter) deep. Standard racks may be configured to house a number of computer systems, e.g., about forty (40) to eighty (80). Each computer system having a system board, power supply, and mass storage. The system boards typically include PCBs having a number of components, e.g., processors, micro-controllers, high-speed video cards, memories, semi-conductor devices, and the like, that dissipate relatively significant amounts of heat during the operation of the respective components. For example, a typical computer system comprising a system board, multiple microprocessors, power supply, and mass storage may dissipate approximately 250 W of power. Thus, a rack containing forty (40) computer systems of this type may dissipate approximately 10 KW of power.

In order to substantially guarantee proper operation, and to extend the life of the electronic packages arranged in the data center, it is necessary to maintain the temperatures of the packages within predetermined safe operating ranges. Operation at temperatures above maximum operating temperatures may result in irreversible damage to the electronic packages. In addition, it has been established that the reliabilities of electronic packages, such as semiconductor electronic devices, decrease with increasing temperature. Therefore, the heat energy produced by the electronic packages during operation must thus be removed at a rate that ensures that operational and reliability requirements are met. Because of the sheer size of data centers and the high number of electronic packages contained therein, it is often expensive to maintain data centers below predetermined temperatures.

The power required to remove the heat dissipated by the electronic packages in the racks is generally equal to about 10 percent of the power needed to operate the packages. However, the power required to remove the heat dissipated by a plurality of racks in a data center is generally equal to about 50 percent of the power needed to operate the packages in the racks. The disparity in the amount of power required to dissipate the various heat loads between racks of data centers stems from, for example, the additional thermodynamic work needed in the data center to cool the air. In one respect, racks are typically cooled with fans that operate to move cooling fluid, e.g., air, across the heat dissipating components; whereas, data centers often implement reverse power cycles to cool heated return air. The additional work required to achieve the temperature reduction, in addition to the work associated with moving the cooling fluid in the data center and the condenser, often add up to the 50 percent power requirement. As such, the cooling of data centers presents problems in addition to those faced with the cooling of racks.

Data centers are typically cooled by operation of one or more air conditioning units. The compressors of the air conditioning units typically require a minimum of about thirty (30) percent of the required cooling capacity to sufficiently cool the data centers. The other components, e.g., condensers, air movers (fans), etc., typically require an additional twenty (20) percent of the required cooling capacity. As an example, a high density data center with 100 racks, each rack having a maximum power dissipation of 10 KW, generally requires 1 MW of cooling capacity. Air conditioning units with a capacity of 1 MW of heat removal generally requires a minimum of 300 KW input compressor power in addition to the power needed to drive the air moving devices, e.g., fans, blowers, etc.

Conventional data center air conditioning units do not vary their cooling fluid output based on the distributed needs of the data center. Typically, the distribution of work among the operating electronic components in the data center is random and is not controlled. Because of work distribution, some components may be operating at a maximum capacity, while at the same time, other components may be operating at various power levels below a maximum capacity. Conventional cooling systems operating at 100 percent, often attempt to cool electronic packages that may not be operating at a level that may cause its temperature to exceed a predetermined temperature range. Consequently, conventional cooling systems often incur greater amounts of operating expenses than may be necessary to sufficiently cool the heat generating components contained in the racks of data centers.

### SUMMARY OF THE INVENTION

According to an embodiment, the invention pertains to an energy management system for one or more data centers. The system includes a system controller and one or more data centers. According to this embodiment, each data center has a plurality of racks, and a plurality of electronic packages. Each rack contains at least one electronic package and a cooling system. The system controller is interfaced with each cooling system and interfaced with the plurality of the electronic packages, and the system controller is configured to distribute workload among the plurality of electronic packages based upon energy requirements.

According to another embodiment, the invention relates to an arrangement for optimizing energy use in one or more data centers. The arrangement includes system controlling means, and one or more data facilitating means, with each data facilitating means having a plurality of processing and electronic means. Each data facilitating means also includes cooling means. According to this embodiment, the system controlling means is interfaced with the plurality of processing and electronic means and also with the cooling means. The system controlling means is configured to distribute workload among the plurality of processing and electronic means.

According to yet another embodiment, the invention pertains to a method of energy management for one or more data centers, with each data center having a cooling system and a plurality of racks. Each rack has at least one electronic package. According to this embodiment, the method includes the steps of determining energy utilization, and determining an optimal workload-to-cooling arrangement. The method further includes the step of implementing the optimal workload-to-cooling arrangement.

### BRIEF DESCRIPTION OF THE DRAWINGS

The present invention is illustrated by way of example and not limitation in the accompanying figures in which like numeral references refer to like elements, and wherein:

FIG. 1A illustrates an exemplary schematic illustration of a data center system in accordance with an embodiment of the invention;

FIG. 1B is an illustration of an exemplary cooling system to be used in a data center room in accordance with an embodiment of the invention;

FIG. 2 illustrates an exemplary simplified schematic illustration of a global data center system in accordance with an embodiment of the invention; and

FIG. 3 is a flowchart illustrating a method according to an embodiment of the invention.

### DETAILED DESCRIPTION OF A PREFERRED EMBODIMENT

According to an embodiment of the present invention, an energy management system is configured to distribute the workload and to manipulate the cooling in one or more data centers, according to desired energy requirements. This may involve the transference of workload from one server to another or from one heat-generating component to another. The system is also configured to adjust the flow of cooling fluid within the data center. Thus, instead of applying cooling fluid throughout the entire data center, the cooling fluid may solely be applied to the locations of working servers or heat generating components.

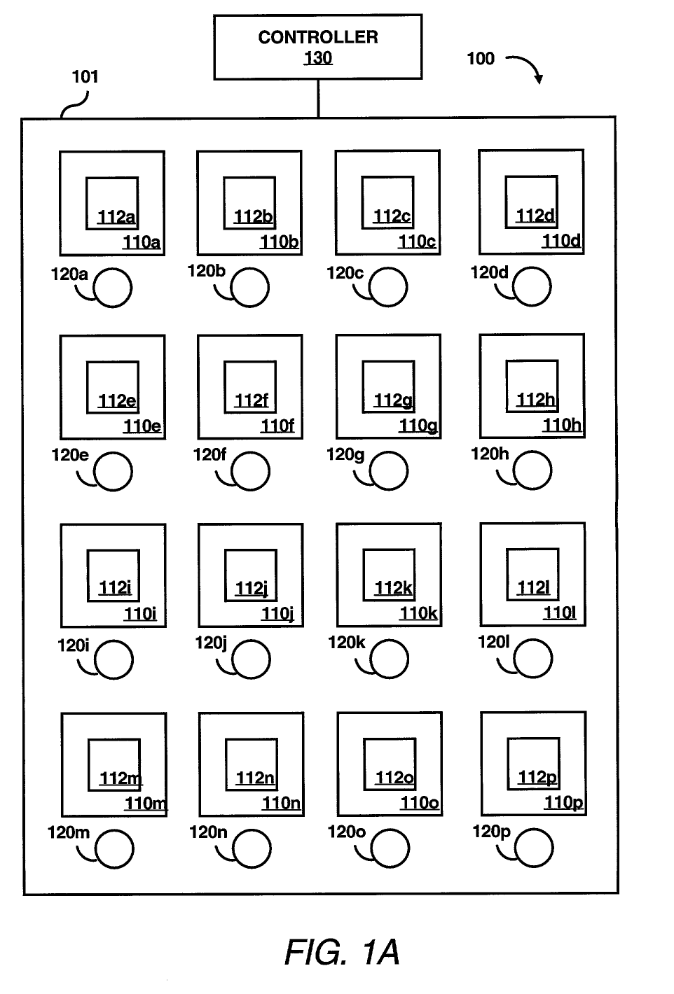

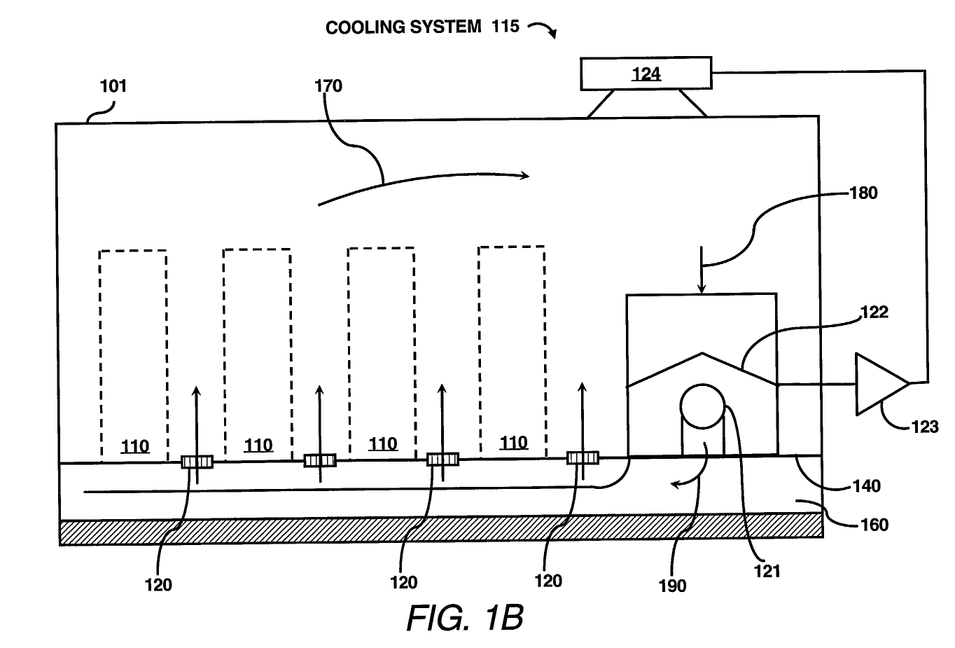

FIG. 1A illustrates a simplified schematic illustration of a data center energy management system 100 in accordance with an embodiment of the invention. As illustrated, the energy management system 100 includes a data center room 101 with a plurality of computer racks 110a-110p and a plurality of cooling vents 120a-120p associated with the computer racks. Although FIG. 1A illustrates sixteen computer racks 110a-110p and associated cooling vents 120a-120p, the data center room 101 may contain any number of computer racks and cooling vents, e.g., fifty computer racks and fifty cooling vents 120a-120p. The number of cooling vents 120a-120p may be more or less than the number of computer racks 110a-110p. The data center energy management system 100 also includes a system controller 130. The system controller 130 controls the overall energy management functions.

Each of the plurality of computer racks 110a-110p generally houses an electronic package 112a-112p. Each electronic package 112a-112p may be a component or a combination of components. These components may include processors, micro-controllers, high-speed video cards, memories, semi-conductor devices, or subsystems such as computers, servers and the like. The electronic packages 112a-112p may be implemented to perform various processing and electronic functions, e.g., storing, computing, switching, routing, displaying, and like functions. In the performance of these processing and electronic functions, the electronic packages 112a-112p generally dissipate relatively large amounts of heat. Because the computer racks 110a-110p have been generally known to include upwards of forty (40) or more subsystems, they may require substantially large amounts of cooling to maintain the subsystems and the components generally within a predetermined operating temperature range.

FIG. 1B is an exemplary illustration of a cooling system 115 for cooling the data center 101. FIG. 1B illustrates an arrangement for the cooling system 115 with respect to the data center room 101. The data center room 101 includes a raised floor 140, with the vents 120 in the floor 140. FIG. 1B also illustrates a space 160 beneath the raised floor 140. The space 160 may function as a plenum to deliver cooling fluid to the plurality of racks 110. It should be noted that although FIG. 1B is an illustration of the cooling system 115, the racks 110 are represented by dotted lines to illustrate the relationship between the cooling system 115 and the racks 110. The cooling system 115 includes the cooling vents 120, a fan 121, a cooling coil 122, a compressor 123, and a condenser 124. As stated above, although the figure illustrates four racks 110 and four vents 120, the number of vents may be more or less than the number of racks 110. For instance, in a particular arrangement, there may be one cooling vent 120 for every two racks 110.

In the cooling system 115, the fan 121 supplies cooling fluid into the space 160. Air is supplied into the fan 121 from the heated air in the data center room 101 as indicated by arrows 170 and 180. In operation, the heated air enters into the cooling system 115 as indicated by arrow 180 and is cooled by operation of the cooling coil 122, the compressor 123, and the condenser 124, in any reasonably suitable manner generally known to those of ordinary skill in the art. In addition, based upon the cooling fluid required by the heat loads in the racks 110, the cooling system 115 may operate at various levels. The cooling fluid generally flows from the fan 121 and into the space 160 (e.g., plenum) as indicated by the arrow 190. The cooling fluid flows out of the raised floor 140 through a plurality of cooling vents 120 that generally operate to control the velocity and the volume flow rate of the cooling fluid there through. It is to be understood that the above description is but one manner of a variety of different manners in which a cooling system 115 may be arranged for cooling a data center room 101.

As outlined above, the system controller 130, illustrated in FIG. 1A, controls the operation of the cooling system 115 and the distribution of work among the plurality of computer racks 110. The system controller 130 may include a memory (not shown) configured to provide storage of a computer software that provides the functionality for distributing the work load among the computer racks 110 and also for controlling the operation of the cooling arrangement 115, including the cooling vents 120, the fan 121, the cooling coil 122, the compressor 123, the condenser 124, and various other air-conditioning elements. The memory (not shown) may be implemented as volatile memory, non-volatile memory, or any combination thereof, such as dynamic random access memory (DRAM), EPROM, flash memory, and the like. It should be noted that a data room arrangement is further described in co-pending application: “Data Center Cooling System”, Ser. No. 09/139,843, assigned to the same assignee as the present application, the disclosure of which is hereby incorporated by reference in its entirety.

The operation of the system controller 130 is further explained using the illustration of FIG. 1A. In operation, the system controller 130, via the associated software, may monitor the electronic packages 112a-112p. This may be accomplished by monitoring the workload as it enters the system and is assigned to a particular electronic package 112a-112p. The system controller 130 may index the workload of each electronic package 112a-112p. Based on the information pertaining to the workload of each electronic package 112a-112p, the system controller 130 may determine the energy utilization of each working electronic package. Controller software may include an algorithm that calculates energy utilization as a function of the workload.

Temperature sensors (not shown) may also be used to determine the energy utilization of the electronic packages. Temperature sensors may be infrared temperature measurement means, thermocouples, thermisters or the like, positioned at various positions in the computer racks 110a-110p, or in the electronic packages 112a-112p themselves. The temperature sensors (not shown) may also be placed in the aisles, in a non-intrusive manner, to measure the temperature of exhaust air from the racks 110a-110p. Each of the temperature sensors may detect temperature of the associated rack 110a-110p and/or electronic package 112a-112p, and based on this detected temperature, the system controller 130 may determine the energy utilization.

Based on the determination of the energy utilization among the electronic packages 112a-112p, the system controller 130 may determine an optimal workload-to-cooling arrangement. The “workload-to-cooling” arrangement refers to the arrangement of the workload among the electronic packages 112a-112p, with respect to the arrangement of the cooling system. The arrangement of the cooling system is defined by the number and location of fluid distributing cooling vents 120a-120p, as well as the rate and temperature at which the fluids are distributed. The optimal workload-to-cooling arrangement may be one in which energy utilization is minimized. The optimal workload-to-cooling arrangement may also be one in which energy cost are minimized.

Based on the above energy requirements, i.e., minimum energy utilization, or minimum energy cost, the system controller 130 determines the optimum workload-to-cooling arrangement. The system controller 130 may include software that performs optimizing calculations. These calculations are based on workload distributions and cooling arrangements.

In one embodiment, the optimizing calculations may be based on a constant workload distribution and a variable cooling arrangement. For example, the calculations may involve permutations of possible workload-to-cooling arrangements that have a fixed workload distribution among the electronic packages 112a-112p, but a variable cooling arrangement. Varying the cooling arrangement may involve varying the distribution of cooling fluids among the vents 120a-120p, varying the rate at which the cooling fluids are distributed, and varying the temperature of the cooling fluids.

In another embodiment, the optimizing calculations may be based on a variable workload distribution and a constant cooling arrangement. For example, the calculations may involve permutations of possible workload-to-cooling arrangements that vary the workload distribution among the electronic packages 112a-112p, but keep the cooling arrangement constant.

In yet another embodiment, the optimizing calculations may be based on a variable workload distribution and a variable cooling arrangement. For example, the calculations may involve permutations of possible workload-to-cooling arrangements that vary the workload distribution among the electronic packages 112a-112p. The calculations may also involve variations in the cooling arrangement, which may include varying the distribution of cooling fluids among the vents 120a-120p, varying the rate at which the cooling fluids are distributed, and varying the temperature of the cooling fluids.

Although permutative calculations are outlined as examples of calculations that may be utilized in the determination of optimized energy usage, other methods of calculations may be employed. For example, initial approximations for an optimized workload-to-cooling arrangement may be made, and an iterative procedure for determining an actual optimized workload-to-cooling arrangement may be performed. Also, stored values of energy utilization for known workload-to-cooling arrangements may be tabled or charted in order to interpolate an optimized workload-to-cooling arrangement. Calculations may also be based upon approximated optimized energy values, from which the workload-to-cooling arrangement is determined.

The optimal workload-to-cooling arrangement may include grouped workloads. Workload grouping may involve shifting a plurality of dispersed server workloads to a single server, or it may involve shifting different dispersed server workloads to grouped or adjacently located servers. The grouping makes it possible to use a reduced number of the cooling vents 120a-120p for cooling the working servers 112a-112p. Therefore, the amount of energy required to cool the servers may be reduced.

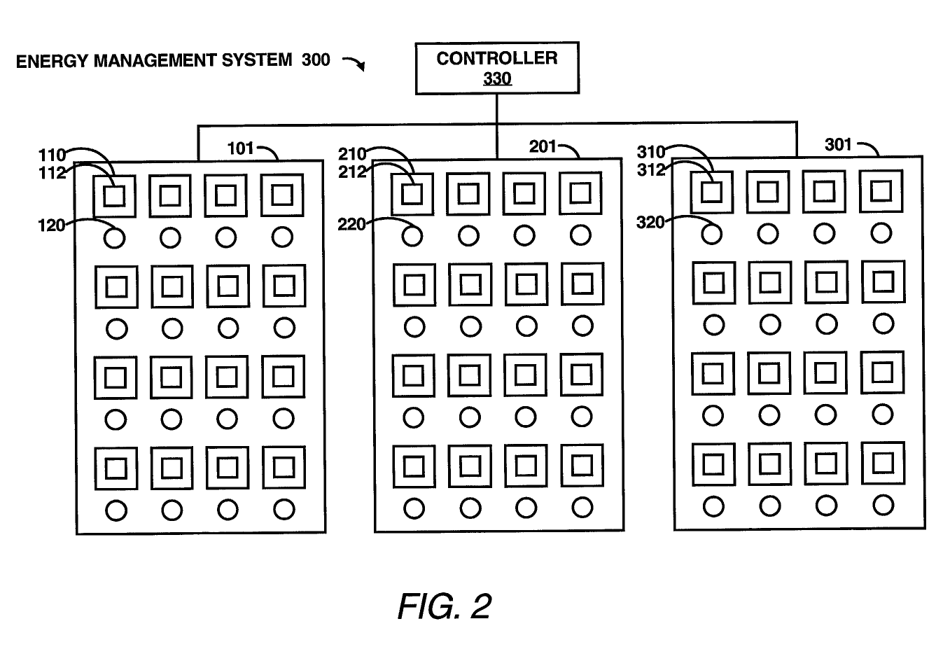

The optimizing process is further explained in following examples. In a first example, the data center energy management system 100 of FIG. 2 contains servers 112a-112p and corresponding cooling vents 120a-120p. Servers 112a, 112e, 112h, and 112m are all working at a maximum capacity of 10 KW. In this example, the maximum working capacity of each of the plurality of servers 112a-112p is 10 KW. In addition, each cooling vent 120a-120p of the cooling system 115 is blowing cooling fluids at a temperature of 55° F. and at a low throttle. The system controller 130 determines the energy utilization of each working server, 112a, 112e, 112h, and 112m. An algorithm associated with the controller 130 may estimate the energy utilization of the servers 112a, 112e, 112h, and 112m by monitoring the workloads of the servers 112a-112p, and performing calculations that estimate the energy utilization as a function of the workload.

The heat energy dissipated by 112a, 112e, 112h, and 112m may also be determined from measurements by sensing means (not shown) located in the servers 112a-112p. Alternatively, the system controller 130 may use a combination of the sensing means (not shown) and calculations based on the workload, to determine the energy utilization of the electronic packages 112a, 112e, 112h, and 112m.

After determining the energy utilization of the servers 112a, 112e, 112h, and 112m, the system controller 130 may determine an optimal workload-to-cooling arrangement. The optimal workload-to-cooling arrangement may be one in which energy utilization is minimized, or one in which energy cost are minimized. In this example, the energy utilization is to be minimized, therefore the system controller 130 performs calculations to determine the most energy efficient workload-to-cooling arrangement.

As outlined above, the optimizing calculations may be performed using different permutations of sample workload-to-cooling arrangements. The optimizing calculations may be based on permutations that have a varying cooling arrangement whilst maintaining a constant workload distribution. The optimizing calculations may alternatively be based on permutations that have a varying workload distribution and a constant cooling arrangement. The calculations may also be based on permutations having varying workload distributions and varying cooling arrangements.

In this example, the optimizing calculations use permutations of sample workload-to-cooling arrangements in which both the workload distribution and the cooling arrangements vary. The system controller 130 includes software that performs optimizing calculations. As stated above, the optimal arrangement may involve the grouping of workloads. These calculations therefore use permutations in which the workload is shifted around from dispersed servers 112a, 112e, 112h, and 112m to servers that are adjacently located or grouped. The permutations also involve different sample cooling arrangements, i.e., arrangements in which some of the cooling vents 120a-120p are closed, or in which the cooling fluids are blown in reduced or increased amounts. The cooling fluids may also be distributed at increased or reduced temperatures.

After performing energy calculations of the different sample workload-to-cooling arrangements, the most energy efficient arrangement is selected as the optimal arrangement. For instance, in accessing the different permutations, the two most energy efficient workload-to-cooling arrangements may include the following groups of servers: A first group of servers 112f, 112g, 112j, and 112k, located substantially in the center of the data center room 101, and a second group of servers 112a, 112b, 112e, and 112f, located at a corner of the data center room 101. Assuming that these two groups of servers utilize a substantially equal amount of energy, then the more energy efficient of the two workload-to-cooling arrangements is dependent upon which cooling arrangement for cooling the servers, is more energy efficient.

The energy utilization associated with the use of the different vents may be different. For instance, some vents may be located in an area in the data center room 101 where they are able to provide better circulation throughout the entire data center room 101, than vents located elsewhere. As a result, some vents may be able to more efficiently maintain, not only operating electronic packages, but also the inactive electronic packages 112a-112p, at predetermined temperatures. Also, the cooling system 115 may be designed in such a manner that particular vents involve the operation of fans that utilize more energy than fans associated with other vents. Differences in energy utilization associated with vents may also occur due to mechanical problems such as clogging etc.

Returning to the example, it may be more efficient to cool the center of the room 101 because the circulation at this location is generally better than other areas in the room. Therefore, the first group, 112f, 112g, 112j, and 112k would be used. Furthermore, the centrally located cooling vents 120f, 120g, 120j, and 120k are the most efficient circulators, so these vents should be used in combination with the first group of servers, 112f, 112g, 112j, and 112k, to optimize energy efficiency. Other vents that are not as centrally located may have a tendency to produce eddies and other undesired circulatory effects. In this example, the optimized workload-to-cooling arrangement involves the use of servers 112f, 112g, 112j, and 112k in combination with cooling vents 120f, 120g, 120j, and 120k. It should be noted that although the outlined example illustrates a one-to-one ratio of cooling vents to racks, it is possible to have a smaller or larger number of cooling vents as compared to racks. Also, the temperature and the rate at which the cooling fluids are distributed may be altered.

In a second example, the system 100 of FIG. 2 contains servers 112a-112p and corresponding cooling vents 120a-120p. Servers 112a, 112e, and 112h are all working at a capacity of 3 KW. Server 112m is operating at a maximum capacity of 10 KW. The maximum working capacity of each of the plurality of servers 112a-112p is 10 KW. In addition, the cooling arrangement 115 is performing with each of the cooling vents 120a-120p blowing cooling fluids at a low throttle at a temperature of 55° F. In a manner as described in the first example, the system controller 130 determines the energy utilization of each working server, 112a, 112e, 112h, and 112m, i.e., by means of, calculations that determine energy utilization as a function of workload, sensing means, or a combination thereof.

After determining the energy utilization, the system controller 130 may optimize the operation of the system 100. According to this example, the system may be optimized according to a minimum energy requirement. As in the first example, the system controller 130 performs optimizing energy calculations for different permutations of workload-to-cooling arrangements. In this example, calculations may involve permutations that vary the workload distribution and the cooling arrangement.

As stated above, the calculations of sample workload-to-cooling arrangements may involve grouped workloads in order to minimize energy requirements. The system controller 130 may perform calculations in which, the workload is shifted around from dispersed servers to servers that are adjacently located or grouped. Because the servers 112a, 112e, and 112h, are operating at 3 KW, and each of the servers 112 have a maximum operating capacity of 10 KW, it is possible to combine these workloads to a single server. Therefore, the calculations may be based on permutations that combine the workloads of servers 112a, 112e, and 112h, as well as shift the workload of server 112m to another server.

After performing energy calculations of the different sample workload-to-cooling arrangements, the most energy efficient arrangement is selected as the optimal arrangement. In this example, the workload-to-cooling arrangement may be one in which the original workload is shifted to servers 112f and 112g with server 112f operating at 9 KW and 112g operating at 10 KW. The optimizing calculations may show that the operation of these servers 112f and 112g, in combination with the use of cooling vents 120f and 120g, may utilize the minimum energy. Again, as outlined above, although the outlined example illustrates a one-to-one ratio of cooling vents to racks, it is possible to have a smaller or larger number of cooling vents as compared to racks.

As stated above, the permutative calculations outlined in the above examples, is but one manner of determining optimized arrangements. Other methods of calculations may be employed. For example, initial approximations for an optimized workload-to-cooling arrangement may be made, and an iterative procedure for determining the actual optimized workload-to-cooling arrangements may be determined. Also, stored values of energy utilization for known workload-to-cooling arrangements may be tabled or charted in order to interpolate an optimized workload-to-cooling arrangement. Calculations may also be based upon approximated optimized energy values, from which the workload-to-cooling arrangement is determined.

It should be noted that the grouping of the workloads might be performed in a manner to minimize the switching of workloads from one server to another. For instance, in the second example, the system controller 130 may allow the server 112m to continue operating at 10 KW. The workload from the other servers 112a, 112e, and 112h may be switched to the server 112n, so that cooling may be provided primarily by the vents 120m and 120n. By not switching the workload from server 112m, the server 112m is allowed to perform its functions without substantial interruption.

Although the examples illuminate situations in which workloads are grouped in order to ascertain an optimal workload-to-cooling arrangement, optimal arrangements may be obtained by separating workloads. For instance, server 112d may be operating at a maximum capacity of 20 KW, with associated cooling vent 120d operating at full throttle to maintain the server at a predetermined safe temperature. The use of the cooling vent 120d at full throttle may be inefficient. In this situation, the system controller 130 may determine that it is more energy efficient to separate the workloads so that servers 112c, 112d, 112g, and 112h all operate at 5 KW because it is easier to cool the servers with divided workloads. In this example, vents 120c, 120d, 120g, and 120h may be used to provide the cooling fluids more efficiently in terms of energy utilization.

It should also be noted that the distribution of workloads and cooling may be performed on a cost-based analysis. According to a cost-based criterion, the system controller 130 utilizes an optimizing algorithm that minimizes energy cost. Therefore in the above example in which the server 112d is operating at 20 KW, the system controller 130 may distribute the workload among other servers, and/or distribute the cooling fluids among the cooling vents 120a-120p, in order to minimize the cost of the energy. The controller 130 may also manipulate other elements of the cooling system 115 to minimize the energy cost, e.g., the fan-speed may be reduced.

FIG. 2 illustrates an exemplary simplified schematic illustration of a global data center system. FIG. 2 shows an energy management system 300 that includes data centers 101, 201, and 301. The data centers 101, 201, and 301 may be in different geographic locations. For instance, data center 101 may be in New York, data center 201 may be in California, and data center 301 may be in Asia. Electronic packages 112, 212, and 312 and corresponding cooling vents 120, 220, and 320 are also illustrated. Also illustrated is a system controller 330, for controlling the operation of the data centers 101, 201, and 301. It should be noted that each of the data centers 101, 201, and 301 may each include a respective system controller without departing from the scope of the invention. In this instance, each system controller may be in communication with each other, e.g., networked through a portal such as the Internet. For simplicity sake, this embodiment of the invention will be described with a single system controller 330.

The system controller 330 operates in a similar manner to the system controller 130 outlined above. According to one embodiment, the system controller 330 operates to optimize energy utilization. This may be accomplished by minimizing the energy cost, or by minimizing energy utilization. In operation, the system controller 330 may monitor the workload and determine the energy utilization of the electronic packages 112, 212, and 312. The energy utilization may be determined by calculations equating the energy utilization as a function of the workload. The energy utilization may also be determined by temperature sensors (not shown) located in and/or in the vicinity of the electronic packages 112, 212, and 312.

Based on the determination of the energy utilization of servers 112, 212, and 312, the system controller 330 optimizes the system 300 according to energy requirements. The optimizing may be to minimize energy utilization or to minimize energy cost. When optimizing according to a minimum energy cost requirement, the system controller 330 may distribute the workload and/or cooling according to energy prices.

For example, if the only active servers are in the data center 201, which for example is located in California, the system controller 330 may switch the workload to the data center 301 or data center 101 in other geographic locations, if the energy prices at either of these locations are cheaper than at data center 201. For instance, if the data center 301 is in Asia where energy is in less demand and cheaper because it is nighttime, the workload may be routed to the data center 301. Alternatively, the climate where a data center is located may have an impact on energy efficiency and energy prices. If the data center 101 is in New York, and it is winter in New York, the system controller 330 may switch the workload to the data center 101. This switch may be made because cooling components such as the condenser (element 124 in FIG. 2B) are more cost efficient at lower temperatures, e.g. 50° F. in New York winter.

The system controller 330 may also be operated in a manner to minimize energy utilization. The operation of the system controller 330 may be in accordance with a minimum energy requirement as outlined above. However, the system controller 330 has the ability to shift workloads (and/or cooling operation) from electronic packages in one data center to electronic packages in data centers at another geographic location. For example, if the only active servers are in the data center 201, which for example is located in California, the system controller 330 may switch the workload to the data center 301 or data center 101 in other geographic locations, if the energy utilization at either of these locations is more efficient than at data center 201. If the data center 101 is in New York, and it is winter in New York, the system controller 330 may switch the workload to the data center 101, because cooling components such as the condenser (element 124 in FIG. 2B) utilize less energy at lower temperatures, e.g. 50° F. in New York winter.

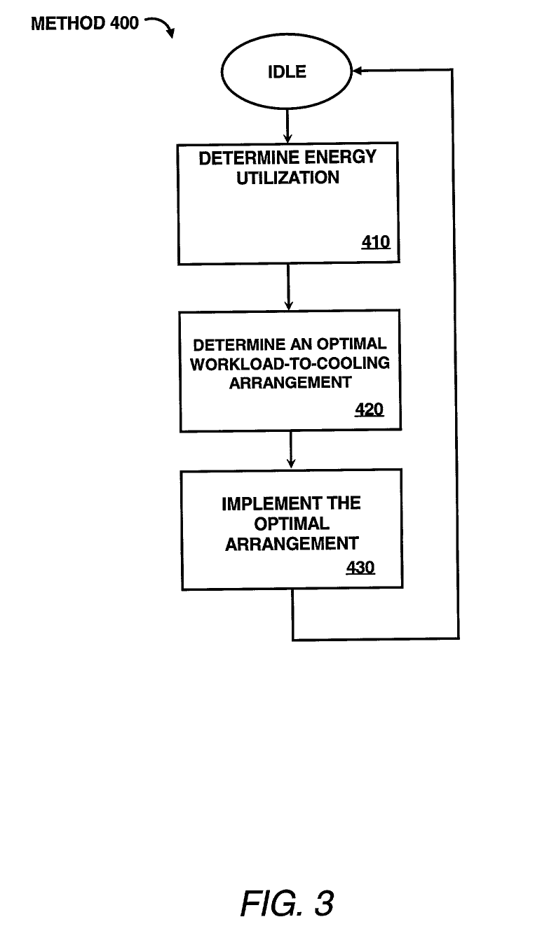

FIG. 3 is a flowchart illustrating a method 400 according to an embodiment of the invention. The method 400 may be implemented in a system such as system 100 illustrated in FIG. 1A or system 300 illustrated in FIG. 3. Each data center has a cooling arrangement with cooling vents and racks, and electronic packages in the data center racks. It is to be understood that the steps illustrated in the method 400 may be contained as a routine or subroutine in any desired computer accessible medium. Such medium including the memory, internal and external computer memory units, and other types of computer accessible media, such as a compact disc readable by a storage device. Thus, although particular reference is made to the controller 130 as performing certain functions, it is to be understood that any electronic device capable of executing the above-described function may perform those functions.

At step 410, energy utilization is determined. In making this determination, the electronic packages 112 are monitored. The step of monitoring the electronic packages 112 may involve the use of software including an algorithm that calculates energy utilization as a function of the workload. The monitoring may also involve the use of sensing means attached to, or in the general vicinity of the electronic packages 112.

At step 420, an optimal workload-to-cooling arrangement is determined. The optimal arrangement may be one in which energy utilization is minimized. The optimal arrangement may also be one in which energy cost are minimized. This may be determined with optimizing energy calculations involving different workload-to-cooling arrangements. In performing the calculations, the workload distribution and/or the cooling arrangement may be varied.

At step 430, the optimal workload-to-cooling arrangement is implemented. Therefore, the workload may be distributed among the electronic packages 112 and the cooling arrangements may be changed for example, by opening and closing vents. The temperature of the cooling may also be adjusted, and the speed of circulating fluids may be changed. After performing step 430, the system may go into an idle state.

It should be noted that, the data, routines and/or executable instructions stored in software for enabling certain embodiments of the present invention may also be implemented in firmware or designed into hardware components.

What has been described and illustrated herein is a preferred embodiment of the invention along with some of its variations. The terms, descriptions and figures used herein are set forth by way of illustration only and are not meant as limitations. Those skilled in the art will recognize that many variations are possible within the spirit and scope of the invention, which is intended to be defined by the following claims—and their equivalents—in which all terms are meant in their broadest reasonable sense unless otherwise indicated.

What is claimed is:

1. An energy management system for one or more data centers, the system comprising:
a system controller; and
one or more data centers, said one or more data centers comprising:
a plurality of racks,
a plurality of electronic packages, wherein said plurality of racks contain at least one electronic package; and
a cooling system,
wherein the system controller is interfaced with one or more of said cooling systems and interfaced with the plurality of the electronic packages, and wherein the system controller is configured to distribute workload among the plurality of electronic packages based upon energy requirements.

2. The system according to claim 1, wherein said one or more cooling systems further comprise a plurality of cooling vents for distributing cooling fluids, and the system controller is configured to regulate cooling fluids through the plurality of cooling vents.

3. The system according to claim 1, wherein the system controller is further configured to distribute the workload to minimize energy utilization.

4. The system according to claim 2, wherein the system controller is further configured to regulate the cooling fluids to minimize energy utilization.

5. The system according to claim 1, wherein the system controller is further configured to distribute the workload to minimize energy cost.

6. The system according to claim 2, wherein the system controller is further configured to regulate the cooling fluids to minimize energy cost.

7. The system according to claim 2, comprising a plurality of data centers, wherein the data centers are in different geographic locations.

8. The system according to claim 7, wherein the system controller is further configured to distribute the workloads among the plurality of data centers in the different geographic locations to minimize energy utilization.

9. The system according to claim 7, wherein the system controller is further configured to distribute the workloads among the plurality of data centers in the different geographic locations to minimize energy cost.

10. The system according to claim 2, wherein each of the plurality of cooling vents is associated with one or more electronic packages.

11. An arrangement for optimizing energy use in one or more data centers, the arrangement comprising:
system controlling means; and
one or more data facilitating means, said one or more data facilitating means comprising:
a plurality of processing and electronic means; and
cooling means;
wherein the system controlling means is interfaced with the plurality of processing and electronic means, and interfaced with the cooling means, wherein the system controlling means is configured to distribute workload among the plurality of processing and electronic means.

12. The arrangement of claim 11, wherein the system controlling means is further configured to distribute the workload to minimize energy utilization.

13. The arrangement of claim 11, wherein the system controlling means is further configured to regulate the cooling means to minimize energy utilization.

14. The arrangement of claim 11, wherein the system controlling means is further configured to distribute the workload to minimize energy cost.

15. The arrangement of claim 11, wherein the system controlling means is further configured to regulate the cooling means to minimize energy cost.

16. The arrangement of claim 11, further comprising a plurality of data facilitating means, wherein the plurality of data facilitating means are in different geographic locations.

17. The arrangement of claim 16, wherein the system controlling means is further configured to distribute the workloads among the plurality of data facilitating means in the different geographic locations to minimize energy utilization.

18. The arrangement of claim 16, wherein the system controlling means is further configured to distribute the workloads among the plurality of data facilitating means in the different geographic locations to minimize energy cost.

19. A method of energy management for one or more data centers, said one or more data centers comprising a cooling system and a plurality of racks, said plurality of racks having at least one electronic package, the method comprising:
determining energy utilization;
determining an optimal workload-to-cooling arrangement; and
implementing the optimal workload-to-cooling arrangement.

20. The method of claim 19, wherein the energy utilization determination step comprises determining the temperatures of the at least one electronic package.

21. The method of claim 19, wherein the energy utilization determination step comprises determining the workload of the at least one electronic package.

22. The method of claim 19, wherein the determination of the optimal workload-to-cooling arrangement comprises performing optimizing calculations.

23. The method of claim 22, wherein in the determination of the optimal workload-to-cooling arrangement, the optimizing calculations are based on a constant workload distribution, and a variable cooling arrangement.

24. The method of claim 22, wherein in the determination of the optimal workload-to-cooling arrangement, the optimizing calculations are based on a variable workload distribution, and a constant cooling arrangement.

25. The method of claim 22, wherein in the determination of the optimal workload-to-cooling arrangement, the optimizing calculations are based on a variable workload distribution, and a variable cooling arrangement.

26. The method of claim 22, wherein in the determination of the optimal workload-to-cooling arrangement, the optimizing calculations are performed to minimize energy utilization.

27. The method of claim 22, wherein in the determination of the optimal workload-to-cooling arrangement, the optimizing calculations are performed to minimize energy cost.

28. The method of claim 19, further comprising:
determining the energy utilization of a plurality of electronic packages located in a plurality of data centers, said plurality of data centers being located in different geographic locations; and
wherein the step of implementing the optimal workload-to-cooling arrangement comprises distributing the workload from at least one electronic package in one data center to another electronic package located in another data center.

29. The method of claim 28, wherein the distributing of the workload from at least one electronic package in one data center to another electronic package located in another data center is based on differences in climate between the data centers.
